(19) United States
(12) Patent Application Publication
(10) Pub. No.: US 2016/0013226 A1
(43) Pub. Date: Jan. 14, 2016

(54) IMAGE SENSOR AND AN IMAGE CAPTURING APPARATUS INCLUDING THE IMAGE SENSOR

(71) Applicant: SAMSUNG ELECTRONICS CO., LTD., Suwon-si (KR)

(72) Inventors: Eun-Sub Shim, Anyang-si (KR); Moo-sup Lim, Yongin-si (KR); Young-Chan Kim, Seongnam-si (KR); Seung-sik Kim, Hwaseong-Si (KR); Min-Seok Oh, Osan-si (KR)

(21) Appl. No.: 14/797,570

(22) Filed: Jul. 13, 2015

(30) Foreign Application Priority Data
Jul. 14, 2014 (KR) 10-2014-0088453

(51) Int. Cl. H01L 27/146; H04N 5/232

(52) U.S. Cl. CPC H01L 27/14603; H01L 27/14627; H01L 27/14621; H01L 27/14623; H04N 5/23212

(57) ABSTRACT

An image sensor includes a pixel array. The pixel array includes a plurality of sensing pixels and at least two focusing pixels adjacent to each other. Each of the sensing pixels is configured to output an image signal corresponding to an amount of light incident on the sensing pixels. The at least two focusing pixels are configured to output a focusing signal corresponding to a phase difference between light incident on the at least two focusing pixels. Each of the sensing pixels and the at least two focusing pixels includes a semiconductor layer including a photodetecting device. Each of the sensing pixels includes a light guide which guides incident light toward the photodetecting device, and each of the at least two focusing pixels does not include the light guide.

### CROSS-REFERENCE TO RELATED APPLICATION

This application claims priority under 35 U.S.C. §119 to Korean Patent Application No. 10-2014-0088453, filed on Jul. 14, 2014, in the Korean Intellectual Property Office, the disclosure of which is incorporated by reference herein in its entirety.

### TECHNICAL FIELD

The present inventive concept relates to an image sensor and an image capturing apparatus including the image sensor, and more particularly, to an image sensor with increased sensitivity and an image capturing apparatus including the image sensor.

### DISCUSSION OF THE RELATED ART

Demand for a high performance image sensor and an image capturing apparatus including the same has been increased with the proliferation of mobile devices. For example, many applications require the image capturing apparatus to perform an image capturing operation accurately within a short period of time.

### SUMMARY

According to an exemplary embodiment of the present inventive concept, there is provided an image sensor. The image sensor includes a pixel array. The pixel array includes a plurality of sensing pixels and at least two focusing pixels. Each of sensing pixels is configured to output an image signal corresponding to an amount of light incident on the sensing pixel. The at least two focusing pixels are adjacent to each other and output a focusing signal corresponding a phase difference between light incident on each of the at least two focusing pixels. Each of the sensing pixels and the at least two focusing pixels comprises a semiconductor layer, a wiring layer, a color filter, and a microlens layer. The semiconductor layer includes a photodetecting device configured to accumulate electric charges generated according to absorbed light from among the incident light. The wiring layer including wirings is disposed on a first surface of the semiconductor layer. The color filter layer and the microlens layer are disposed on a first surface of the wiring layer. The color filter layer selectively transmits the incident light according to a wavelength of the incident light. The microlens layer selectively focuses the incident light onto the photodetecting device. Each of the sensing pixels includes a light guide which guides light incident via the color filter layer and the microlens layer toward the photodetecting device. Each of the focusing pixels does not include the light guide.

In an exemplary embodiment of the present inventive concept, each of the focusing pixels may further include a shielding layer disposed in the wiring layer to shield the photodetecting device from some of the light incident via the color filter layer and the microlens layer.

In an exemplary embodiment of the present inventive concept, the shielding layer may include metal.

In an exemplary embodiment of the present inventive concept, the shielding layer may be formed using at least one of the wirings included in the wiring layer.

In an exemplary embodiment of the present inventive concept, the shielding layer may be formed by extending a first wiring located adjacent to the semiconductor layer from among the wirings included in the wiring layer.

In an exemplary embodiment of the present inventive concept, the pixel array may be controlled according to a global shutter method, and each of the sensing pixels and the at least two focusing pixels may further include a charge storage device that temporarily stores the electric charges accumulated in the photodetecting device.

In an exemplary embodiment of the present inventive concept, the shielding layer may be formed by extending a metal layer that blocks light incident on the photodetecting device.

In an exemplary embodiment of the present inventive concept, the shielding layers in the at least two focusing pixels may be adjacent to each other in a first direction.

In an exemplary embodiment of the present inventive concept, the shielding layers in the at least two focusing pixels may be adjacent to each other in a second direction perpendicular to the first direction.

In an exemplary embodiment of the present inventive concept, the shielding layers in the at least two focusing pixels may be spaced apart from each other in a first direction.

In an exemplary embodiment of the present inventive concept, the shielding layers in the at least two focusing pixels may be adjacent to each other in a second direction perpendicular to the first direction.

In an exemplary embodiment of the present inventive concept, the pixel array may include a bayer pattern, and the at least two focusing pixels may be disposed on a red (R) region or a blue (B) region of the bayer pattern.

In an exemplary embodiment of the present inventive concept, the light guide may be formed in the wiring layer using a material having a lower refractive index than a material of the wiring layer, and the light guide may reflect incident light when an incidence angle of the incident light is greater than a first angle.

In an exemplary embodiment of the present inventive concept, the light guide may include a polymer-based material.

In an exemplary embodiment of the present inventive concept, the image sensor may further include a row driver and a pixel signal processing unit. The row driver may be configured to apply a row signal to the pixel array. The pixel signal processing unit may be configured to receive the image signal or the focusing signal from first sensing pixels of the plurality of sensing pixels or first focusing pixels of the at least two focusing pixels to process the image signal or the focusing signal. The first sensing pixels and the second focusing pixels may be activated by the row signal.

According to an exemplary embodiment of the present inventive concept, an image sensor is provided. The image sensor includes a pixel array and a row driver. The pixel array includes a plurality of pixels. The plurality of pixels is activated, based on a first selection signal, to absorb light, to accumulate first electric charges corresponding to the absorbed light, and to output a first image signal or a first focusing signal. The row driver is configured to output the first selection signal to activate first pixels of the plurality of pixels. The plurality of pixels includes a sensing pixel and at least two focusing pixels. The sensing pixel is configured to output the first image signal corresponding to an amount of light incident on the sensing pixel. The at least two focusing pixels are adjacent to each other and are configured to output the first focusing signal corresponding to a phase difference between respective lights incident on the at least two focusing pixels. Each of the sensing pixel and the at least two focusing pixels includes a semiconductor layer. The semiconductor layer includes a photodetecting device configured to accumulate the first electric charges. The sensing pixel includes a light guide which guides incident light toward the photodetecting device, and each of the at least focusing pixels does not include the light guide.

In an exemplary embodiment of the present inventive concept, the image sensor may further include a pixel signal processing unit. The pixel signal processing unit may include a storage unit to store location information of the at least two focusing pixels.

In an exemplary embodiment of the present inventive concept, each of the sensing pixel and the at least two focusing pixels may further include a wiring layer and a color filter. The wiring layer may be disposed on a first surface of the semiconductor layer, and the wiring layer may include wirings. The color filter layer and a microlens layer may be disposed on a first surface of the wiring layer. The color filter layer may selectively transmit the incident light according to a wavelength of the incident light and the microlens layer may selectively focus the incident light onto the photodetecting device.

In an exemplary embodiment of the present inventive concept, the pixel array may include a bayer pattern, and the at least two focusing pixels may be disposed on a red (R) region or a blue (B) region of the bayer pattern.

According to an exemplary embodiment of the present inventive concept, an image capturing apparatus is provided. The image capturing apparatus includes a lens and an image sensor. The image sensor is configured to receive light incident through the lens. The image sensor includes a plurality of sensing pixels and at least two focusing pixels. Each sensing pixel is configured to output an image signal corresponding to an amount of light incident on the sensing pixel. The at least two focusing pixels are adjacent to each other. The at least two focusing pixels are configured to output a focusing signal corresponding to a phase difference between light incident on each of the at least two focusing pixels. Each of the sensing pixels and the at least two focusing pixels includes a semiconductor layer, a wiring layer, a color filter layer, and a microlens layer. The semiconductor layer includes a photodetecting device. The photodetecting device is configured to accumulate electric charges generated according to absorbed light of the incident light. The wiring layer is disposed on a first surface of the semiconductor layer. The wiring layer includes wirings. The color filter layer and the microlens layer are disposed on a first surface of the wiring layer. The color filter layer selectively transmits the incident light according to a wavelength of the incident light. The microlens layer selectively focuses the incident light onto the photodetecting device. Each of the sensing pixels includes a light guide which guides light incident via the color filter layer and the microlens layer toward the photodetecting device. Each of the focusing pixels does not include the light guide.

### BRIEF DESCRIPTION OF THE DRAWINGS

Exemplary embodiments of the present inventive concept will be more clearly understood from the following detailed description taken in conjunction with the accompanying drawings, in which:

FIG. 1 is a diagram of an image sensor according to an exemplary embodiment of the present inventive concept;

FIGS. 2A and 2B are diagrams illustrating functions of a shielding layer in a focusing pixel included in the image senor of FIG. 1 according to an exemplary embodiment of the present inventive concept;

FIG. 3 is a diagram of the image sensor including a pixel array of FIG. 1 in more detail according to an exemplary embodiment of the present inventive concept;

FIGS. 4A and 4B are diagrams illustrating a pixel pattern in a pixel array of FIG. 1 according to an exemplary embodiment of the present inventive concept;

FIGS. 5A, 5B, 6A, 6B, 7A, and 7B are diagrams each illustrating locations of shielding layers in two adjacent focusing pixels arranged as shown in FIG. 4B according to an exemplary embodiment of the present inventive concept;

FIG. 8 is a cross-sectional view illustrating an exemplary embodiment of the present inventive concept in which a shielding layer of FIG. 1 is formed;

FIG. 9 is a circuit diagram of a pixel when the image sensor of FIG. 1 uses a global shutter method according to an exemplary embodiment of the present inventive concept;

FIGS. 10A and 10B are cross-sectional views illustrating an exemplary embodiment of the present inventive concept in which a shielding layer is formed in a focusing pixel having a structure of FIG. 9;

FIG. 11 includes cross-sectional views for explaining influence of a light guide in the image sensor of FIG. 1 according to an exemplary embodiment of the present inventive concept;

FIG. 12 is a cross-sectional view of a focusing pixel in the image senor of FIG. 1 according to an exemplary embodiment of the present inventive concept;

FIGS. 13A and 13B are diagrams of cameras including the image sensor of FIG. 1 according to an exemplary embodiment of the present inventive concept;

FIG. 14 is a block diagram of an image sensor chip according to an exemplary embodiment of the present inventive concept;

FIG. 15 is a block diagram of a system including the image sensor chip of FIG. 14 according to an exemplary embodiment of the present inventive concept; and

FIG. 16 is a block diagram of an electronic system including an image sensor and an interface according to an exemplary embodiment of the present inventive concept.

### DETAILED DESCRIPTION OF THE EMBODIMENTS

The present inventive concept will now be described more fully with reference to the accompanying drawings, in which exemplary embodiments of the present inventive concept are shown. Like reference numerals in the drawings denote like elements.

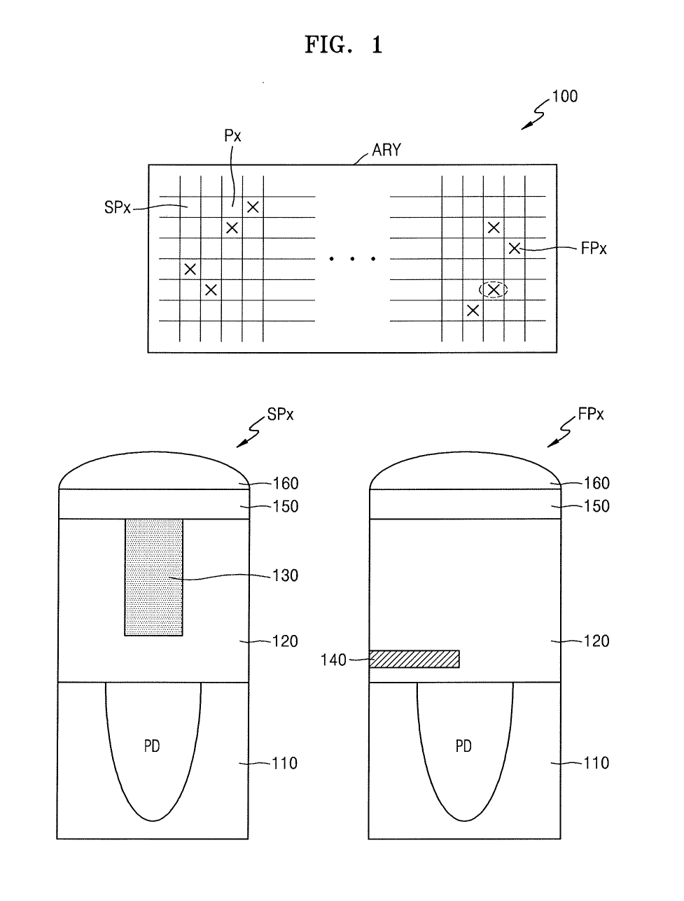

FIG. 1 is a diagram of an image sensor 100 according to an exemplary embodiment of the present inventive concept. Referring to FIG. 1, the image sensor 100 includes a pixel array ARY including a plurality of pixels Px arranged in a two-dimensional (2D) matrix. The image sensor 100 may be a complementary metal oxide semiconductor (CMOS) image sensor (CIS). The CIS controls a control device that controls or processes optical signals in the image sensor 100 by using CMOS technology, and thus the image sensor 100 may be manufactured in a simple way and may be fabricated as a chip having a plurality of signal processing devices. The image sensor 100 may be a front-side illumination (FSI) image sensor.

Referring to FIG. 1, each of the pixels Px in the pixel array ARY may be a sensing pixel SPx or a focusing pixel FPx. For example, the image sensor 100 according to an exemplary embodiment of the present inventive concept is an image sensor performing both an image sensing and an auto focusing via one pixel array ARY.

Each of the sensing pixels SPx senses an amount of incident light and outputs an image signal corresponding to the sensed amount of light. The image signal is used to form an image of the corresponding sensing pixel SPx. In addition, each of the focusing pixels FPx outputs a focusing signal corresponding to a phase difference between light incident on the focusing pixel FPx and light incident on an adjacent focusing pixel FPx. The focusing signal is used to adjust a location of a lens of an image capturing apparatus including the image sensor 100, and thus an auto focusing function is performed. The number of focusing pixels FPx may be less than that of the sensing pixels SPx. The focusing pixels FPx may be arranged randomly or regularly with respect to the locations or the number of the sensing pixels SPx.

Each of the sensing pixel SPx and the focusing pixel FPx may include a semiconductor layer 110, a wiring layer 120, a color filter layer 150, and a micro lens layer 160. Since sensing pixels SPx and focusing pixels FPx are included in the same pixel array ARY as described above, a semiconductor layer 110, a wiring layer 120, a color filter layer 150, and a micro lens layer 160 included in each sensing pixel SPx may be respectively formed of the same materials as those included in each focusing pixel FPx or may respectively have the same sizes as those included in each focusing pixel FPx. Each of the sensing pixels SPx includes a light guide 130 to effectively concentrate light incident via the microlens layer 150 on a photodetecting device PD. In addition, each of the focusing pixels FPx may not include the light guide 130 or may include a different type of light guide from the light guide 130, and thus a phase difference between the light incident on the focusing pixel FPx and the light incident on an adjacent focusing pixel FPx may be sensed. FIG. 1 illustrates an exemplary embodiment of the present inventive concept in which each of the focusing pixels FPx includes no light guide. The light guide 130 will be described in more detail later with reference to FIG. 11. Since the sensing pixel SPx senses an accurate amount of incident light, the sensing pixel SPx may not include a shield layer 140 unlike the focusing pixel FPx. The respective structures of the sensing pixel SPx and the focusing pixel FPx will now be described in more detail.

The semiconductor layer 110 may be, for example, a bulk substrate, an epitaxial substrate, a silicon-on-insulator (SOI) substrate, or the like. The semiconductor layer 110 may include the photodetecting device PD. The photodetecting device PD may be a photodiode, and the photodiode may absorb light incident through the microlens layer 160 and the color filter layer 150 to generate electric current. If a charge transfer path between the photodetecting device PD and the outside is blocked while the photodetecting device PD is absorbing light, electric charges corresponding to the current generated by the photodetecting device PD may be accumulated in the photodetecting device PD. Since the number of electric charges accumulated in the photodetecting device PD increases as an amount of light absorbed by the photodetecting device PD increases, an intensity of light absorbed by the photodetecting device PD may be sensed according to the number of electric charges accumulated in the photodetecting device PD. The semiconductor layer 110 may further include transistors for sensing the electric charges accumulated in the photodetecting device PD as an electrical signal or for resetting the electric charges accumulated in the photodetecting device PD by the focusing pixel FPx.

The wiring layer 120 contacts a surface of the semiconductor layer 110, and may include a plurality of wirings formed of a conductive material. An empty space of the wiring layer 120 in which no wiring is formed may be filled with an insulator (e.g., oxide). The electric charges accumulated in the photodetecting device PD may be output to the outside via the wiring layer 120. In the embodiment of FIG. 1, the light guide 130 is further formed in the wiring layer 120 of the sensing pixel SPx, and the shielding layer 140 is further formed in the wiring layer 120 of the focusing pixel FPx.

The color filter layer 150 and the microlens layer 160 may be sequentially stacked on the other surface of the semiconductor layer 110. The color filter layer 150 transmits the light incident through the microlens layer 160 so that only light having a particular wavelength, which is, for example, determined by the color filter layer 150, may be incident on the photodetecting device PD. The microlens layer 160 may focus the incident light toward the photodetecting device PD.

The shielding layer 140 of the focusing pixel FPx may be formed on a portion of an upper surface of the photodetecting device PD, and thus the light incident via the microlens layer 160 and the color filter layer 150 may be prevented from being transmitted to the photodetecting device PD. As described above, the shielding layer 140 may be formed within the wiring layer 120. The shielding layer 140 may include a material that does not transmit light, for example, metal. The shielding layer 140 will be described in more detail later.

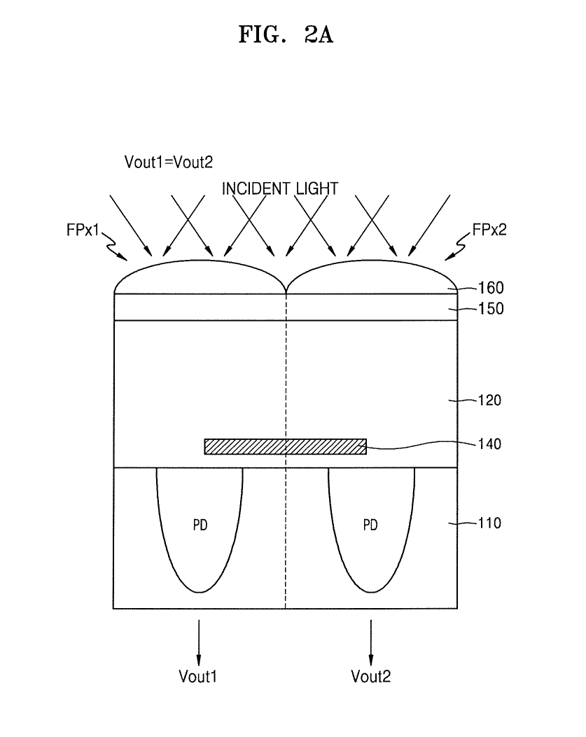

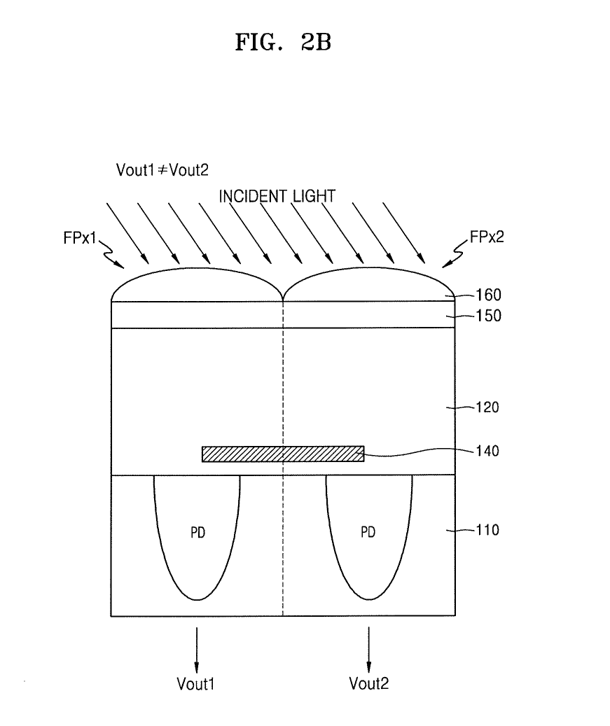

FIGS. 2A and 2B are diagrams illustrating functions of a shielding layer 140 in a focusing pixel FPx included in the image sensor of FIG. 1 according to an exemplary embodiment of the present inventive concept. Referring to FIG. 2A, a first focusing pixel FPx1 and a second focusing pixel FPx2 are adjacent to each other to describe the function of the focusing pixel FPx in detail. Referring to FIG. 2A, in a case where a subject is focused by a lens of an image capturing apparatus including the image sensor 100, a phase of light incident on the image sensor 100 is constant. Thus, the amount of light absorbed by the respective photodetecting devices PD of the first focusing pixel FPx1 and the second focusing pixel FPx2 may be equal to each other even if some of the light is blocked by the shielding layer 140. Therefore, electrical signals output from the first focusing pixel FPx1 and the second focusing pixel FPx2, for example, a first output voltage Vout1 and a second output voltage Vout2, may be equal to each other.

Referring to FIG. 2B, in a case where the subject is not focused by the lens of the image capturing apparatus including the image sensor 100, a phase difference between the light incident on the image sensor 100 is generated. Thus, the amount of the light absorbed by the respective photodetecting devices PD of the first focusing pixel FPx1 and the second focusing pixel FPx2 may be different from each other due to the shielding layer 140. Therefore, electrical signals output from the first focusing pixel FPx1 and the second focusing pixel FPx2, for example, a first output voltage Vout1 and a second output voltage Vout2, may be different from each other.

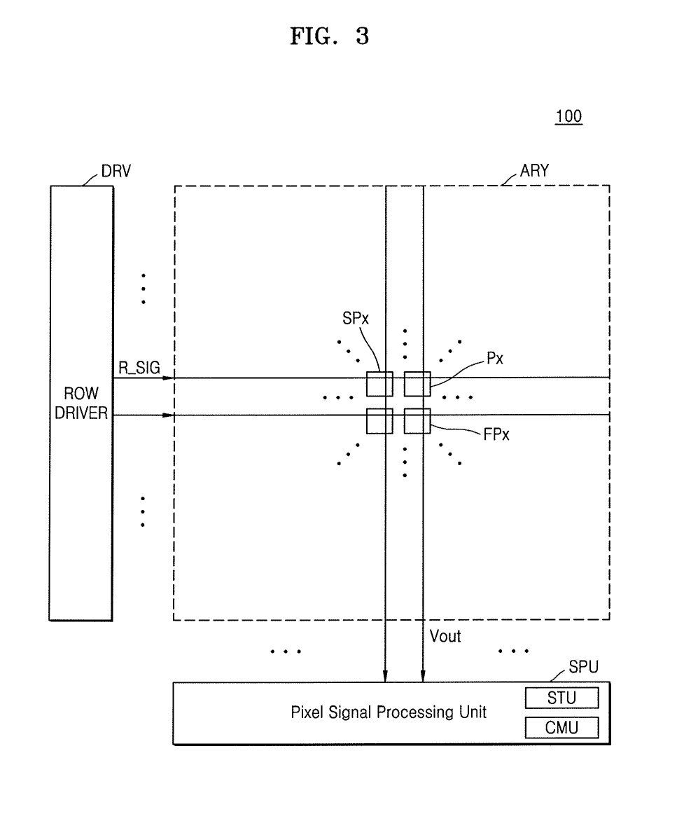

FIG. 3 is a diagram of the image sensor 100 including the pixel array ARY of FIG. 1 in more detail according to an exemplary embodiment of the present inventive concept. The image sensor 100 may include the pixel array ARY, a row driver DRV, and a pixel signal processing unit SPU. The pixel array ARY may include a plurality of pixels Px. The row driver DRV may output a row signal R_SIG, and the row signal R_SIG may be input to the pixel array ARY. The row signal R_SIG may include a plurality of signals, and the plurality of signals may respectively control the pixels Px included in the pixel array ARY.

The pixel signal processing unit SPU may receive an output voltage Vout output from at least one pixel Px included in the pixel array ARY, and may measure a magnitude of the output voltage Vout. A plurality of pixels Px in each row of the pixel array ARY may share an identical row signal R_SIG, and a plurality of pixels Px in each column of the pixel array ARY may share a signal line through which the output voltage Vout is output.

As described above, the pixel array ARY according to the present embodiment may include both sensing pixels SPx and focusing pixels FPx. The pixel signal processing unit SPU may store location information of the focusing pixels FPx. To this end, the pixel signal processing unit SPU may include a storage unit STU. In addition, the pixel signal processing unit SPU may include a comparing unit CMU that generates a result of comparing the output voltages Vout of adjacent focusing pixels FPx with each other based on the location information. For example, the comparing unit CMU may output a result of comparing a first output voltage Vout1 of the first focusing pixel FPx1 with a second output voltage Vout2 of the second focusing pixel FPx2 of FIG. 2. The comparison result may be used by logic of the image capturing apparatus including the image sensor 100 to perform the auto focusing function.

For example, exemplary embodiments of the present inventive concept are not limited thereto. The pixel signal processing unit SPU may output only the respective output voltages Vout of the sensing pixels SPx and the focusing pixels FPx, and the logic of the image capturing apparatus including the image sensor 100 may compare the first output voltage Vout1 of the first focusing pixel FPx1 with the second output voltage Vout2 of the second focusing pixel FPx2, which are adjacent to each other, as shown in FIG. 2.

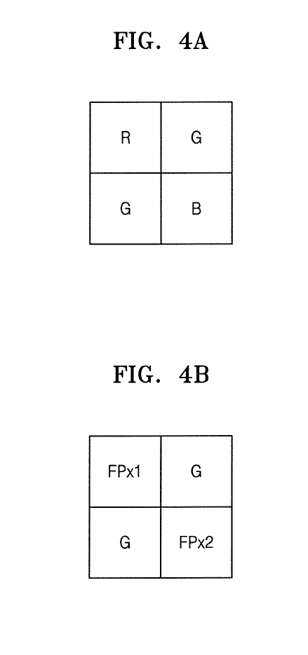

FIGS. 4A and 4B are diagrams illustrating a pixel pattern in a pixel array ARY of FIG. 1 according to an exemplary embodiment of the present inventive concept. Referring to FIG. 1 and FIG. 4A, each of the pixels Px in the pixel array ARY may be arranged in a bayer pattern that includes twice as many green (G) filters than red (R) filters and blue (B) filters in the color filter layer 150. However, exemplary embodiments of the present inventive concept are not limited thereto. Each of the pixels Px in the pixel array ARY may be arranged in a non-bayer pattern. Hereinafter, each of the pixels Px in the pixel array ARY is assumed to be arranged in a bayer pattern for convenience of description.

Referring to FIGS. 1 and 4B, in the pixel array ARY in which pixels Px are arranged in the bayer pattern, the focusing pixel FPx may be disposed on an R region or a B region. For example, in a layer pattern of RGGB, the first focusing pixel FPx1 may be disposed on an R region, and the second focusing pixel FPx2 may be disposed on a B region. As described above, the auto focusing function may be performed based on a difference between the output voltages (e.g., Vout1 and Vout2) from at least a pair of focusing pixels FPx that are adjacent to each other. Since human eyes are sensitive to a brightness difference, the focusing pixels FPx are disposed on the R region or the B region that is related to color, rather than a G region that is related to brightness. Thus, influence of the focusing pixels FPx on the image sensing may be reduced in the pixel array ARY including the sensing pixels SPx and the focusing pixels FPx. However, in the image sensor according to an exemplary embodiment of the present inventive concept or an electronic device including the image sensor, the focusing pixels FPx may be disposed on the G region.

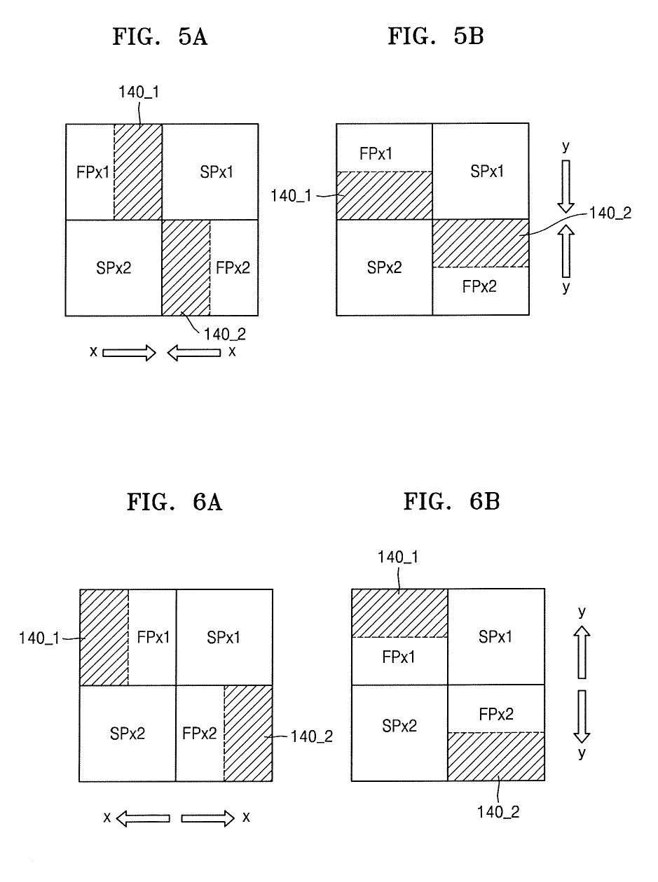

FIGS. 5A, 5B, 6A, 6B, 7A, and 7B are diagrams each illustrating locations of the shielding layers in two adjacent focusing pixels arranged as shown in FIG. 4B according to an exemplary embodiment of the present inventive concept. In FIGS. 5A, 5B, 6A, 6B, 7A, and 7B, a material formed on the shielding layer (e.g., 140_1 or 140_2) of the focusing pixel (e.g., FPx1 or FPx2) is not shown to clearly illustrate the location of the shielding layer. Referring to FIGS. 5A and 5B, shielding layers 140_1 and 140_2 each in the first and second focusing pixels FPx1 and FPx2 may be disposed to be adjacent to each other. For example, as shown in FIG. 5A, the shielding layer 140_1 of the first focusing pixel FPx1 and the shielding layer 140_2 of the second focusing pixel FPx2 may be disposed on regions adjacent to each other in a first direction x. In an exemplary embodiment of the present inventive concept, as shown in FIG. 5B, the shielding layer 140_1 of the first focusing pixel FPx1 and the shielding layer 140_2 of the second focusing pixel FPx2 may be disposed on regions adjacent to each other in a second direction y substantially perpendicular to the first direction x.

Referring to FIGS. 6A and 6B, the shielding layers 140_1 and 140_2 of the first and second focusing pixels FPx1 and FPx2 may be disposed to be spaced apart from each other. For example, as shown in FIG. 6A, the shielding layer 140_1 of the first focusing pixel FPx1 and the shielding layer 140_2 of the second focusing pixel FPx2 may be disposed on regions that are spaced apart from each other in the first direction x. In an exemplary embodiment of the present inventive concept, as shown in FIG. 6B, the shielding layer 140_1 of the first focusing pixel FPx1 and the shielding layer 140_2 of the second focusing pixel FPx2 may be disposed on regions spaced apart from each other in the second direction y.

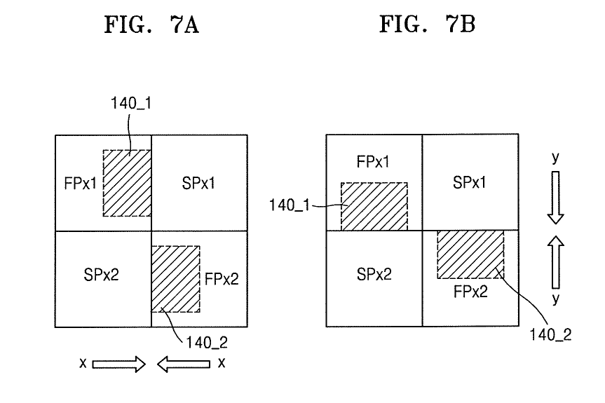

FIGS. 5A, 5B, 6A, and 6B illustrate examples in which the shielding layer 140_1 of the first focusing pixel FPx1 and the shielding layer 140_2 of the second focusing pixel FPx2 are formed to have sides having substantially the same lengths as those of sides of the focusing pixels FPx1 and FPx2, respectively. However, exemplary embodiments of the present inventive concept are not limited thereto. Referring to FIGS. 7A and 7B, sides of the shielding layers 140_1 and 140_2 of the first and second focusing pixels FPx1 and FPx2 may have lengths shorter than those of the sides of the focusing pixels FPx1 and FPx2, respectively.

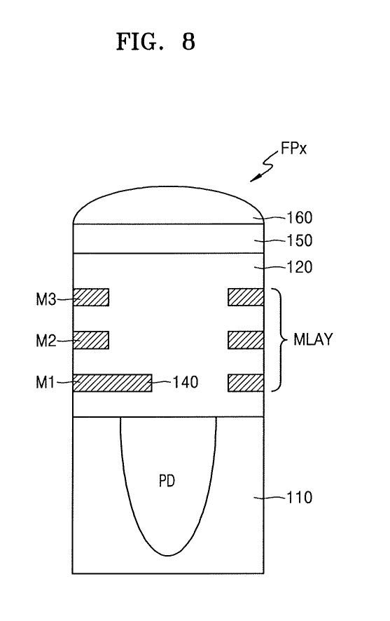

FIG. 8 is a cross-sectional view illustrating an exemplary embodiment of the present inventive concept in which a shielding layer 140 of FIG. 1 is formed. Referring to FIG. 8, the shielding layer 140 may be formed using any of a plurality of wirings (e.g., first, second, and third wirings M1, M2, and M3) formed in the wiring layer 120. For example, the shielding layer 140 may be formed by extending the first wiring M1 in a direction that enables the first wiring M1 to be adjacent to the photodetecting device PD. The first wiring M1 may be closest to the semiconductor layer 110 from among the first, second, and third wirings M1, M2, and M3. As described above, the shielding layer 140 is disposed to be separate from a portion of the upper surface of the photodetecting device PD by a predetermined distance, and thus the photodetecting device PD is shielded from some of the light incident thereon. The first, second, and third wirings M1, M2, and M3 are used to supply power to a circuit device of the semiconductor layer 110 or transmit or receive a signal to or from the circuit device of the semiconductor layer 110.

A different number of wirings from the number of wirings illustrated in FIG. 8 may be formed in the wiring layer 120, and the shielding layer 140 may be formed by using a wiring other than the first wiring M1. As such, according to the image sensor 100 in an exemplary embodiment of the present inventive concept, a shielding layer included in each focusing pixel is formed by extending a part of a wiring, and thus the manufacturing process of the image sensor 100 is simplified and the manufacturing costs thereof are reduced.

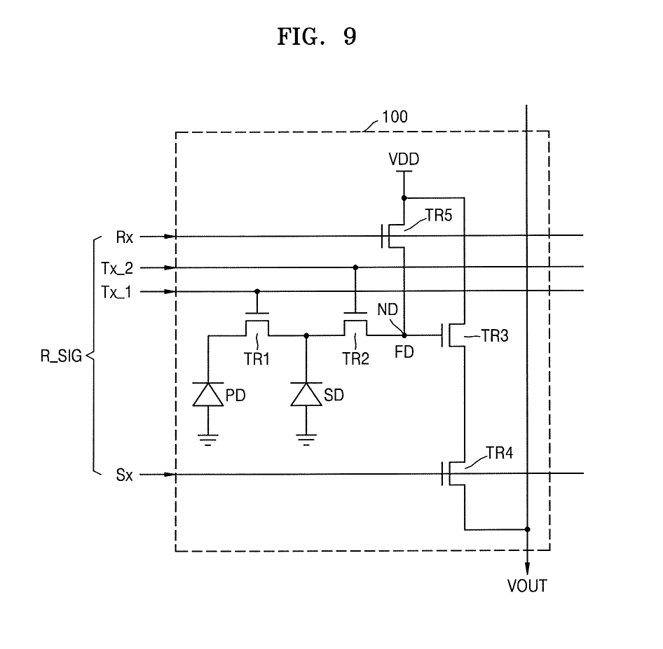

FIG. 9 is a circuit diagram of a pixel when the image sensor 100 of FIG. 1 uses a global shutter method according to an exemplary embodiment of the present inventive concept. Referring to FIGS. 1 and 9, the pixel array ARY including a plurality of pixels Px in the image sensor 100 may be controlled using a global shutter method. An erroneous image may be generated due to difference in the numbers (e.g., sensed number) of electric charges accumulated in the photodetecting device PD according to different physical locations on the pixel array ARY under identical conditions. By using the global shutter method, the erroneous image may be prevented from being generated. To support a global shutter, each pixel Px may include a charge storage device SD that temporarily stores the electric charges accumulated in the photodetecting device PD. The charge storage device SD functions to temporarily store electric charges that are generated as the photodetecting device PD absorbs light.

A unit pixel (e.g., each pixel Px of FIG. 1) of the image sensor 100 may receive a row signal R_SIG from the outside and may output an output voltage VOUT to the outside. The row signal R_SIG may be applied to the gates of a plurality of transistors included in a semiconductor layer 110 of the unit pixel to control the transistors. The row signal R_SIG may include a reset signal Rx, first and second transfer signals Tx_l and Tx_2, and a selection signal Sx. The output voltage VOUT may be determined according to an intensity of light detected by the photodetecting device PD.

Each pixel Px may include the photodetecting device PD, the charge storage device SD, a first transfer transistor TR1, a second transfer transistor TR2, a source-follower transistor TR3, a selection transistor TR4, and a reset transistor TR5. In addition, the pixel Px may include a floating diffusion FD which is a node to which the second transfer transistor TR2, the source-follower transfer transistor TR3, and the reset transistor TR5 are electrically connected.

For example, the photodetecting device PD that absorbs light and converts the light into an electrical signal may include a photodiode, a photogate, a phototransistor, and an oxide transistor. The charge storage device SD may temporarily store electric charges that are accumulated in the photodetecting device PD. For example, the charge storage device SD may include a capacitor and a diode. Although it is illustrated in FIG. 9 that the photodetecting device PD is a photodiode and the charge storage device SD is a diode, exemplary embodiments of the present inventive concept are not limited thereto.

The first transfer transistor TR1 may pass through or block from the charge storage device SD the electric charges that are accumulated in the photodetecting device PD, according to the first transfer signal Tx_1. For example, when the photodetecting device PD absorbs light and accumulates electric charges, the first transfer signal Tx_I having a voltage that may turn off the first transfer transistor TR1 may be applied to a gate of the first transfer transistor TR1. The second transfer transistor TR2 may pass through or block from the floating diffusion FD the electric charges that are stored in the charge storage device FD, according to the second transfer signal Tx_2. For example, to output the electric charges stored in the charge storage device SD to the outside of the pixel Px via the floating diffusion FD, the second transfer signal Tx_2 having a voltage that may turn on the second transfer transistor TR2 may be applied to a gate of the second transfer transistor TR2.

The source-follower transistor TR3 may amplify a voltage of the floating diffusion FD, and the selection transistor TR4 may selectively output the amplified voltage according to the selection signal Sx. The reset transistor TR5 may change a voltage of the floating diffusion FD to a reset voltage that is close to a power voltage by connecting or disconnecting the floating diffusion FD and a power supply VDD according to the reset signal Rx. As such, the pixel Px, which includes an element that amplifies an electrical signal obtained by converting light absorbed by the photodetecting device PD, is referred to as an active pixel sensor (APS). The present embodiment may be applied not only to the pixel Px of FIG. 9 but also to any of other APSs including the photodetecting device PD and the charge storage device SD.

A charge transfer between the photodetecting device PD and the charge storage device SD may be controlled by the gate of the first transfer transistor TR1. The floating diffusion FD may be formed within the semiconductor layer 110 and may accommodate the electric charges stored in the charge storage device SD. A voltage corresponding to the electric charges accommodated by the floating diffusion FD may be amplified and output to the outside of the pixel Px.

The second transfer transistor TR2 may form a charge transfer path between the charge storage device SD and the floating diffusion FD. If a charge transfer path between the photodetecting device PD and the outside is blocked while the photodetecting device PD absorbs light, electric charges corresponding to the current generated by the photodetecting device PD may be accumulated in the photodetecting device PD. Since the number of electric charges accumulated in the photodetecting device PD increases according to an intensity of light absorbed by the photodetecting device PD, an intensity of light absorbed by the photodetecting device PD may be sensed according to the number of electric charges accumulated in the photodetecting device PD.

FIG. 9 is a circuit diagram of a pixel of an image sensor 100 that uses a global shutter method. A pixel Px of the image sensor 100 that uses a global shutter method may have a different structure from the structure illustrated in FIG. 9.

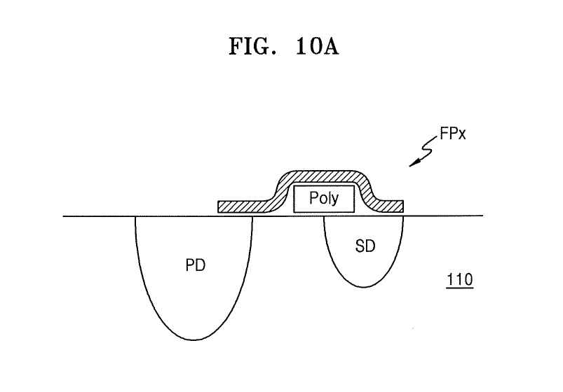

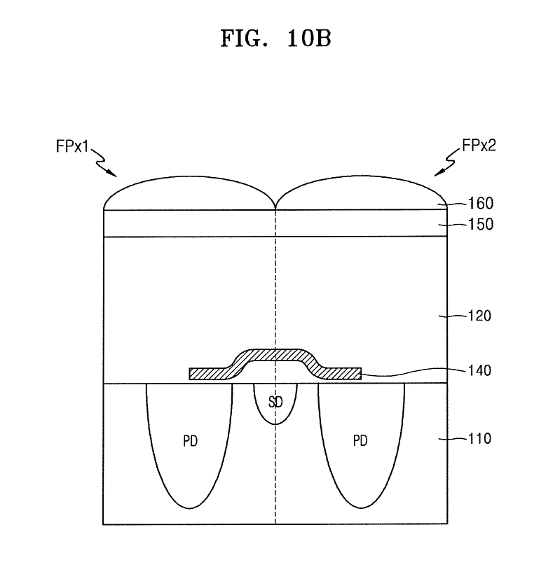

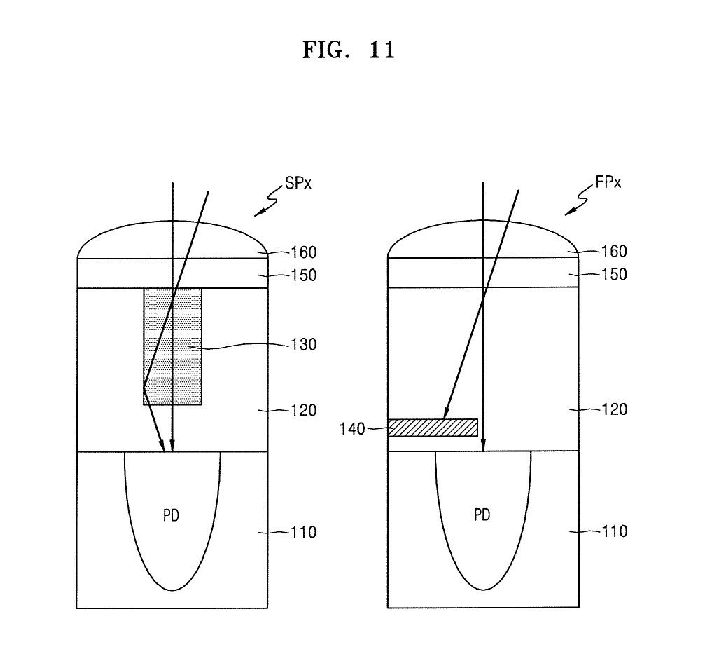

FIGS. 10A and 10B are cross-sectional views illustrating an exemplary embodiment of the present inventive concept in which a shielding layer is formed in a focusing pixel FPx having a structure of FIG. 9. Referring to FIGS. 1, 9, and 10A, light incident on the charge storage device SD illustrated in FIG. 9 may affect the number of electric charges that are stored in the charge storage device SD. In this case, the charge storage device SD is included because the exemplary embodiment described with reference to FIG. 9 uses a global shutter method. For example, when the charge storage device SD is a diode, the charge storage device SD may accumulate electric charges generated according to absorbed light, like a photodiode. Accordingly, the number of electric charges that are temporarily stored in and then output by the charge storage device SD to the outside of a unit device may include errors. Thus, a metal layer (which is hatched) that shields the charge storage device SD from light incident thereon may be included. For example, tungsten may be deposited on an upper surface (including an upper surface of a poly gate of the charge storage device SD) of the charge storage device SD on which light is incident.

In this case, the shielding layer 140 may be formed by extending the metal layer on the upper surface of the charge storage device SD up to a region over a portion of the upper surface of the photodetecting device PD. The image sensor 100 according an exemplary embodiment of the present inventive concept may produce an accurate imageby using a global shutter method, and may simplify the manufacturing process of the image sensor 100 and reduce the manufacturing cost thereof by forming a shielding layer in each focusing pixel by extending a metal layer. The shielding layer may shield the storage device SD on which light is incident.

Referring to FIGS. 1, 9, and 10B, the charge storage device SD may be formed in the semiconductor layer 110 and located between the respective photodetecting devices PD of the first focusing pixel FPx1 and the second focusing pixel FPx2. The first focusing pixel FPx1 is located adjacent to the second focusing pixel FPx2. The shielding layer 140 may be formed by extending the metal layer on the upper surface of the charge storage device SD up to regions over portions of the upper surfaces of the respective photodetecting devices PD of the two adjacent focusing pixels FPx1 and FPx2.

FIG. 11 includes cross-sectional views illustrating an influence of the light guide 130 in the image sensor of FIG. 1 according to an exemplary embodiment of the present inventive concept. Referring to FIGS. 1 and 11, a first light beam among light beams incident on the sensing pixel SPx may typically not be introduced into the photodetecting device PD when an incident angle of the first light beam is greater than a certain angle (e.g., a critical angel). However, in the case shown in FIG. 11 in which the light guide 130 is included in the sensing pixel SPx, the light guide 130 may guide the first light beam into the photodetecting device PD, and thus the first light beam may be introduced into the photodetecting device PD. The light guide 130 is formed of a material having a lower refractive index than a material (e.g., oxide) with which the wiring layer 120 is filled, and thus may reflect the incident light when an incident angle of the incident light is greater than a critical angle. For example, the light guide 130 may be formed of a polymer-based material.

As such, the light guide 130 included in the sensing pixel SPx may reduce a sensitivity difference between the center of the pixel array ARY and the edge thereof. For example, when light is radiated from an identical light source, light may be perpendicularly incident on the photodetecting device PD in a sensing pixel SPx located at the center of the pixel array ARY and thus the light may be inclined and incident with a certain angle on the photodetecting device PD in a sensing pixel SPx located at the edge of the pixel array ARY. In this case, the number of electric charges accumulated in the photodetecting device PD is relatively large in the sensing pixel SPx located at the center of the pixel array ARY and the number of electric charges accumulated in the photodetecting device PD is relatively small in the sensing pixel SPx located at the edge of the pixel array ARY. Thus, a sensitivity difference may be generated. When a sensitivity of the sensing pixel SPx varies according to a physical location on the pixel array ARY, an inaccurate image may be produced. A light guide 130 included in a sensing pixel SPx located at the edge of the pixel array ARY may guides a light beam incident on the sensing pixel SPx toward the photodetecting device PD, and thus the sensitivity difference may be reduced as described above.

In addition, if the light guide 130 is included in a focusing pixel FPx for detecting a phase difference that is generated due to different incidence angles as in FIG. 2, as in the sensing pixel SPx, the focusing pixel FPx may not perform its function, because light reflected by a sidewall of the light guide 130 is introduced into the photodetecting device PD of the focusing pixel FPx and accordingly the phase difference may not be detected. In the image sensor 100 according to an exemplary embodiment of the present inventive concept in which both sensing pixels and focusing pixels are included in an identical pixel array, formation of a light guide 130 in the sensing pixel SPx is different from that in the focusing pixel FPx as illustrated in FIG. 11. Thus, a sensitivity and a relative illumination (RI) of the sensing pixel SPx may be increased and an accurate phase difference may be detected by the focusing pixel FPx. Therefore, the image sensor 100 according to an exemplary embodiment of the present inventive concept may generate an accurate image.

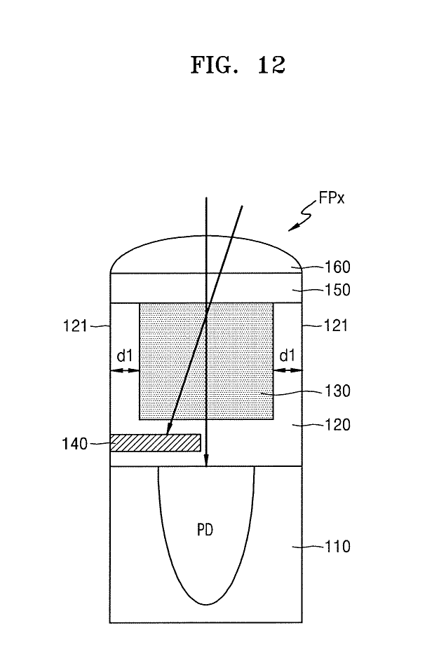

Although it illustrated in FIG. 11 that only the sensing pixel SPx includes the light guide 130 and the focusing pixel FPx includes no light guides to make formation of the light guide 130 in the sensing pixel SPx differ from that in the focusing pixel FPx, exemplary embodiments of the present inventive concept are not limited thereto. As will be described below with reference to FIG. 12, the focusing pixel FPx may also include the light guide 130 and a phase difference may be detected.

FIG. 12 is a cross-sectional view of a focusing pixel FPx in the image sensor of FIG. 1 according to an exemplary embodiment of the present inventive concept. A focusing pixel FPx of FIG. 12 includes a light guide 130, unlike in FIG. 1. The light guide 130 included in the focusing pixel FPx is different from the light guide 130 included in the sensing pixel SPx. For example, the light guide 130 included in the focusing pixel FPx may be wider than the light guide 130 included in the sensing pixel SPx. Accordingly, when light beams are respectively incident on the sensing pixel SPx and the focusing pixel FPx with substantially an identical incident angle, the light guide 130 included in the sensing pixel SPx may guides the incident light beam toward the photodetecting device PD and the light guide 130 included in the focusing pixel FPx may not guide the incident light beam. Thus, the light beam incident on the focusing pixel FPx may be blocked by the shielding layer 140 and may not be introduced into the photodetecting device PD of the focusing pixel FPx, and accordingly the focusing pixel FPx may detect a phase difference from the incident angle of the light beam.

To detect the phase difference, the light guide 130 included in the focusing pixel FPx may be formed as widely as possible. For example, the light guide 130 included in the focusing pixel FPx may have a width such that the light guide 130 is separate from a wiring, other than the shielding layer formed in the wiring layer 120, by a first distance d1. In FIG. 12, for convenience of description, it is assumed that the second and third wirings M2 and M3 of FIG. 8 except for the shielding layer 140 extend up to a line 121. The first distance d1 may be set to be a minimum separation distance from a wiring, which is allowed by a process, for example, 0.1 μm.

As such, an image sensor 100 according to an exemplary embodiment of the present inventive concept may increase a sensitivity of sensing pixels and enable focusing pixels to detect phase differences by including a light guide in each focusing pixel where the light guide of each focusing pixel is different from a light guide of each sending pixel. Although the light guide included in each focusing pixel is wider than that included in each sensing pixel in FIG. 12, exemplary embodiments of the present inventive concept are not limited thereto. In an image sensor 100 according to an exemplary embodiment of the present inventive concept, the light guide included in each focusing pixel has a higher refractive index than that included in each sensing pixel. Thus, when light beams are respectively incident on the focusing pixel and the sensing pixel with substantially an identical incident angle, the focusing pixel may not guide the incident light beam unlike the sensing pixel and the incident light beam may be blocked by a shielding layer.

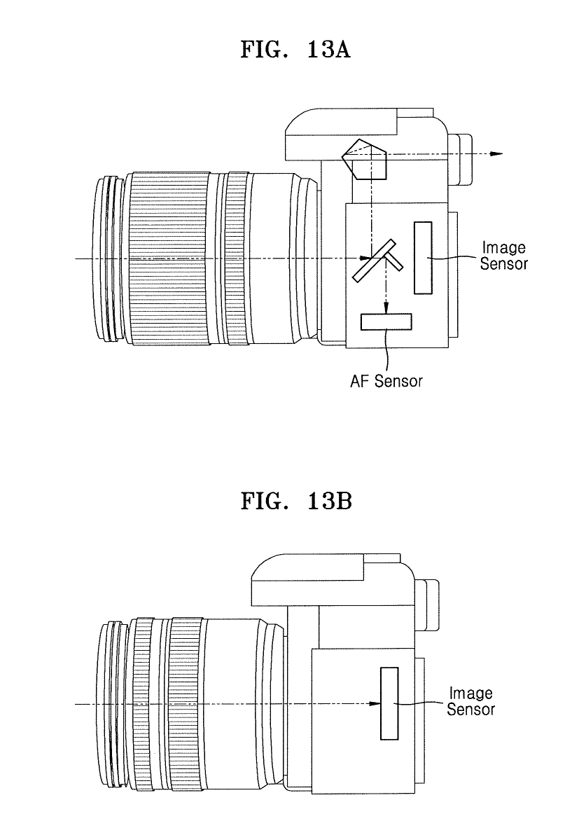

FIGS. 13A and 13B are diagrams of cameras including the image sensor 100 of FIG. 1 according to an exemplary embodiment of the present inventive concept. Referring to FIGS. 1, 13A, and 13B, the image sensor 100 according to an exemplary embodiment of the present inventive concept may be included in an image capturing apparatus. For example, the image sensor 100 may be included in a digital camera. In the image capturing apparatus according to an exemplary embodiment of the present inventive concept, the sensing pixels SPx and the focusing pixels FPx are included in the pixel array ARY of the image sensor 100 as shown in FIG. 13B unlike a camera including an additional auto focusing (AF) sensor for performing an auto focusing operation shown in FIG. 13A. Therefore, the camera including the image sensor 100 according to an exemplary embodiment of the present inventive concept may not include an additional AF sensor, as shown in FIG. 13B.

The camera of FIG. 13B receives the light incident through a lens, and may control an actuator of the lens based on a difference between output voltages from at least a pair of focusing pixels FPx in the image sensor 100. In the camera of FIG. 13A including an AF sensor in addition to the image sensor, some of the light transmitted through the lens of the camera may be incident on at least two AF sensors so that an actuator of the lens may be controlled based on a difference between phases of the respective lights incident on the AF sensors.

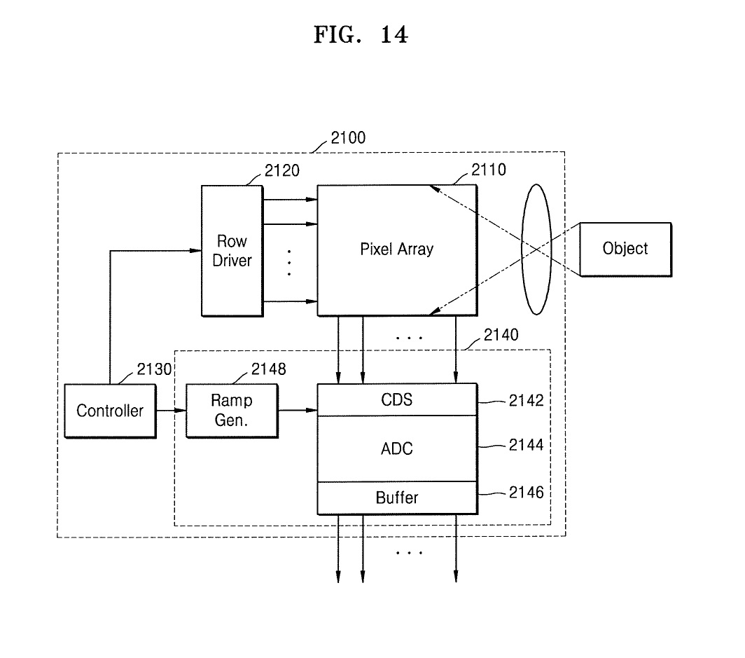

FIG. 14 is a block diagram of an image sensor chip 2100 according to an exemplary embodiment of the present inventive concept. As shown in FIG. 14, the image sensor chip 2100 may include a pixel array 2110, a controller 2130, a row driver 2120, and a pixel signal processing unit 2140. The pixel array 2110 may include a plurality of pixels that are arranged in a two-dimension (2D) matrix form like the pixel array ARY shown in FIG. 1, and each of the pixels may include a photodetecting device PD. The photodetecting device PD absorbs light to generate electric charges, and electrical signals (e.g., output voltages) generated according to the generated electric charges may be provided to the pixel signal processing unit 2140 via a vertical signal line. Each row of the pixels included in the pixel array 2110 may provide one output voltage at a time, and accordingly, the pixels included in a row of the pixel array 2110 may be simultaneously activated according to a selection signal output by the row driver 2120. The pixels included in the selected row may provide the output voltage according to an intensity of absorbed light to an output line of a corresponding column of the pixel array 2110.

The pixel array 2110 may include the sensing pixels SPx and the focusing pixels FPx like in the pixel array ARY of FIG. 1. Like the pixel array ARY of FIG. 1, the pixel array 2110 may have a different light guide 130 in each of the focusing pixels FPx from that in each of the sensing pixels SPx to increase a sensitivity and detect an accurate phase difference.

The controller 2130 may control the row driver 2120 so that the pixel array 2110 absorbs the light and accumulates the electric charges or outputs the electrical signals corresponding the accumulated electric charges to the outside of the pixel array 2110. In addition, the controller 2130 may control the pixel signal processing unit 2140 to measure an output voltage provided by the pixel array 2110.

The pixel signal processing unit 2140 may include a correlated double sampler (CDS) 2142, an analog-digital converter (ADC) 2144, and a buffer 2146. The CDS 2142 may sample and hold the output voltage provided by the pixel array 2110. The CDS 2142 may perform a double sampling on a certain noise level and a level of the output voltage to output a level corresponding to a difference between the noise level and the level of the output voltage. In addition, the CDS 2142 may receive a ramp signal generated by a ramp signal generator 2148, compare the ramp signal with the level corresponding to the difference between the noise level and the level of the output voltage, and output a result of the comparison to the ADC 2144.

The ADC 2144 may convert an analog signal corresponding to the comparison result received from the CDS 2142 into a digital signal. The buffer 2146 may receive and store the digital signal, and the stored digital signal may be sequentially output to the outside of the image sensor chip 2100 to be transmitted to an image processor.

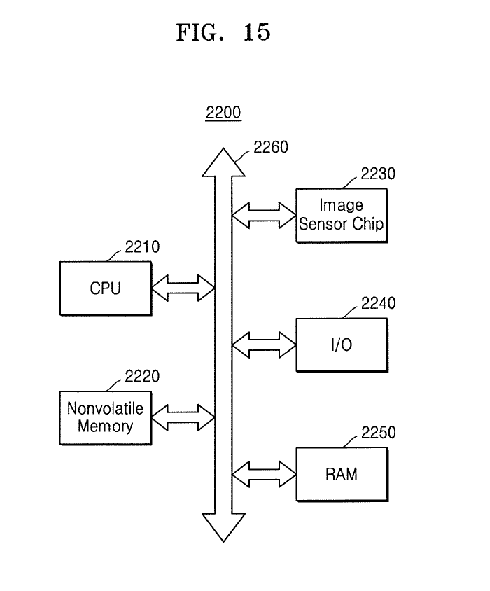

FIG. 15 is a block diagram of a system 2200 including the image sensor chip 2100 of FIG. 14 according to an exemplary embodiment of the present inventive concept. The system 2200 may be a computing system, a camera system, a scanner, a car navigation system, a video phone, a security system, a motion detection system that require image data, or the like.

As shown in FIG. 15, the system 2200 may include a central processing unit (CPU) (or a processor) 2210, a non-volatile memory 2220, an image sensor chip 2230, an input/output (I/O) device 2240, and a random access memory (RAM) 2250. The CPU 2210 may communicate with the non-volatile memory 2220, the image sensor chip 2230, the I/O device 2240, and the RAM 2250 via a bus 2260. The image sensor chip 2230 may be implemented as an independent semiconductor chip, or may be integrated with the CPU 2210 into one semiconductor chip. The image sensor chip 2230 included in the system 2200 of FIG. 15 may include the pixels according to the above-described exemplary embodiments of the present inventive concept. For example, the image sensor chip 2230 includes the pixel array ARY including both the sensing pixels SPx and the focusing pixels FPx, and each focusing pixel FPx has a different light guide 130 from that each of the sensing pixels SPx to increase a sensitivity and detect an accurate phase difference.

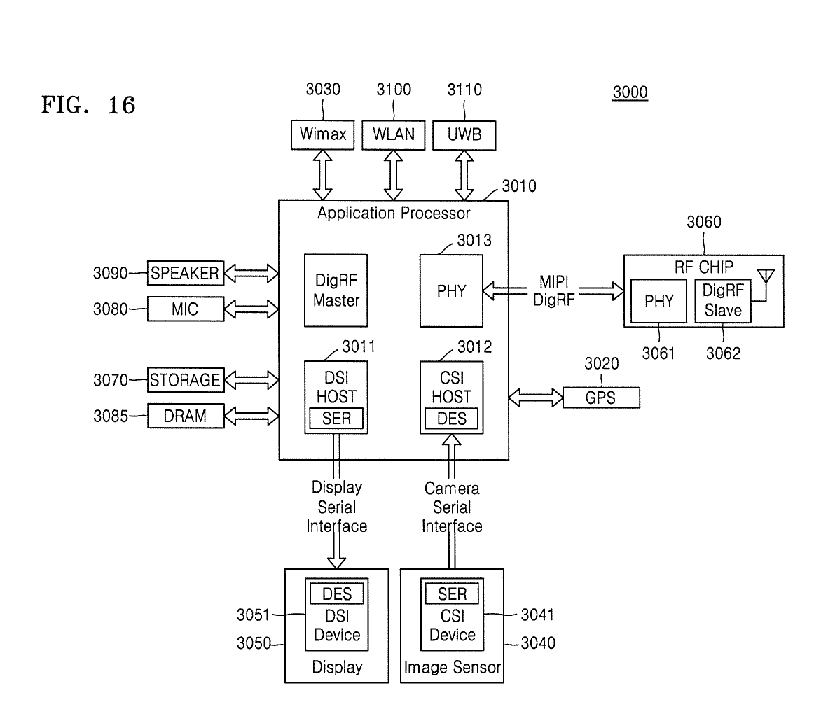

FIG. 16 is a block diagram of an electronic system 3000 including an image sensor and an interface according to an exemplary embodiment of the present inventive concept. Referring to FIG. 16, the electronic system 3000 may be a data processing apparatus (e.g., a mobile phone, a personal digital assistant (PDA), a portable multimedia player (PMP), or a smartphone) capable of using or supporting a mobile industry processor interface (MIPI). The electronic system 3000 may include an application processor 3010, an image sensor chip 3040, and a display 3050.

A camera serial interface (CSI) host 3012 provided in the application processor 3010 may serially communicate with a CSI device 3041 of the image sensor 3040 via a CSI. For example, the CSI host 3012 may include a light deserializer, and the CSI device 3041 may include a light serializer. A display serial interface (DSI) host 3011 provided in the application processor 3010 may serially communicate with a DSI device 3051 of the display 3050 via a DSI. For example, the DSI host 3011 may include a light serializer, and the DSI device 3051 may include a light deserializer.

The electronic system 3000 may further include a radio frequency (RF) chip 3060 that may communicate with the application processor 3010. A PHY 3013 of the electronic system 3000 and a PHY 3061 of the RF chip 3060 may transmit or receive data to or from each other according to MIPI DigRF. The electronic system 3000 may further include a global positioning system (GPS) device 3020, a storage 3070, a microphone 3080, a dynamic RAM (DRAM) 3085, and a speaker 3090, and the electronic system 3000 may perform communication by using a worldwide interoperability for microwave access (WiMAX) 3030, a wireless local area network (WLAN) 3100, and an ultra wide band (UWB) 3110.

While the present inventive concept has been particularly shown and described with reference to exemplary embodiments thereof, it will be understood that various changes in form and details may be made therein without departing from the spirit and scope of the inventive concept as defined by the following claims.

What is claimed is:

1. An image sensor comprising:
a pixel array comprising:
a plurality of sensing pixels, each sensing pixel configured to output an image signal corresponding to an amount of light incident on the sensing pixel; and
at least two focusing pixels adjacent to each other, the at least two focusing pixels configured to output a focusing signal corresponding to a phase difference between light incident on each of the at least two focusing pixels,
wherein each of the sensing pixels and the at least two focusing pixels comprises:
a semiconductor layer including a photodetecting device configured to accumulate electric charges generated according to absorbed light of the incident light;
a wiring layer disposed on a first surface of the semiconductor layer, the wiring layer including wirings; and
a color filter layer and a microlens layer disposed on a first surface of the wiring layer, wherein the color filter layer selectively transmits the incident light according to a wavelength of the incident light and the microlens layer selectively focuses the incident light onto the photodetecting device,
wherein each of the sensing pixels comprises a light guide which guides light incident via the color filter layer and the microlens layer toward the photodetecting device, and each of the focusing pixels does not comprise the light guide.

2. The image sensor of claim 1, wherein each of the focusing pixels further comprises a shielding layer disposed in the wiring layer to shield the photodetecting device from some of the light incident via the color filter layer and the microlens layer.

3. The image sensor of claim 2, wherein the shielding layer comprises metal.

4. The image sensor of claim 2, wherein the shielding layer is formed using at least one of the wirings included in the wiring layer.

5. The image sensor of claim 2, wherein the shielding layer is formed by extending a first wiring located adjacent to the semiconductor layer from among the plurality of wirings included in the wiring layer.

6. The image sensor of claim 2, wherein the pixel array is controlled according to a global shutter method, and
each of the sensing pixels and the at least two focusing pixels further comprises a charge storage device that temporarily stores the electric charges accumulated in the photodetecting device.

7. The image sensor of claim 6, wherein the shielding layer is formed by extending a metal layer that blocks light incident on the photodetecting device.

8. The image sensor of claim 2, wherein the shielding layers in the at least two focusing pixels are adjacent to each other in a first direction.

9. The image sensor of claim 8, wherein the shielding layers in the at least two focusing pixels are adjacent to each other in a second direction perpendicular to the first direction.

10. The image sensor of claim 2, wherein the shielding layers in the at least two focusing pixels are spaced apart from each other in a first direction.

11. The image sensor of claim 10, wherein the shielding layers in the at least two focusing pixels are adjacent to each other in a second direction perpendicular to the first direction.

12. The image sensor of claim 1, wherein
the pixel array includes a bayer pattern, and
the at least two focusing pixels are disposed on a red (R) region or a blue (B) region of the bayer pattern.

13. The image sensor of claim 1, wherein the light guide is formed in the wiring layer using a material having a lower refractive index than a material of the wiring layer, and the light guide reflects incident light when an incidence angle of the incident light is greater than a first angle.

14. The image sensor of claim 1, wherein the light guide includes a polymer-based material.

15. The image sensor of claim 1, further comprising:
a row driver configured to apply a row signal to the pixel array; and
a pixel signal processing unit configured to receive the image signal or the focusing signal from first sensing pixels of the plurality of sensing pixels or first focusing pixels of the at least two focusing pixels to process the image signal or the focusing signal,
wherein the first sensing pixels and the second focusing pixels are activated by the row signal.

16. An image sensor comprising:
a pixel array including a plurality of pixels, wherein the plurality of pixels is activated, based on a first selection signal, to absorb light, to accumulate first electric charges corresponding to the absorbed light, and to output a first image signal or a first focusing signal; and
a row driver configured to output the first selection signal to activate the plurality of pixels,
wherein the plurality of pixels comprises:
a sensing pixel configured to output the first image signal corresponding to an amount of light incident on the sensing pixel; and
at least two focusing pixels adjacent to each other, the at least two focusing pixels configured to output the first focusing signal corresponding to a phase difference between respective lights incident on the at least two focusing pixels,
wherein each of the sensing pixel and the at least two focusing pixels comprises a semiconductor layer including a photodetecting device configured to accumulate the first electric charges,
wherein the sensing pixel comprises a light guide which guides incident light toward the photodetecting device, and each of the at least focusing pixels does not comprise the light guide.

17. The image sensor of claim 16, further comprising a pixel signal processing unit including a storage unit configured to store location information of the at least two focusing pixels.

18. The image sensor of claim 16, wherein each of the sensing pixel and the at least two focusing pixels further comprises:
a wiring layer disposed on a first surface of the semiconductor layer, the wiring layer including wirings; and
a color filter layer and a microlens layer disposed on a first surface of the wiring layer,
wherein the color filter layer selectively transmits the incident light according to a wavelength of the incident light and the microlens layer selectively focuses the incident light onto the photodetecting device.

19. The image sensor of claim 16, wherein the pixel array includes a bayer pattern, and the at least two focusing pixels are disposed on a red (R) region or a blue (B) region of the bayer pattern.

20. An image capturing apparatus comprising;
a lens; and
an image sensor configured to receive light incident through the lens, the image sensor comprises:
a plurality of sensing pixels, each sensing pixel configured to output an image signal corresponding to an amount of light incident on the sensing pixel; and
at least two focusing pixels adjacent to each other, the at least two focusing pixels configured to output a focusing signal corresponding to a phase difference between light incident on each of the at least two focusing pixels,
wherein each of the sensing pixels and the at least two focusing pixels comprises:
a semiconductor layer including a photodetecting device configured to accumulate electric charges generated according to absorbed light of the incident light;
a wiring layer disposed on a first surface of the semiconductor layer, the wiring layer including wirings; and
a color filter layer and a microlens layer disposed on a first surface of the wiring layer,
wherein the color filter layer selectively transmits the incident light according to a wavelength of the incident light and the microlens layer selectively focuses the incident light onto the photodetecting device,
wherein each of the sensing pixels comprises a light guide which guides light incident via the color filter layer and the microlens layer toward the photodetecting device, and each of the focusing pixels does not comprise the light guide.
